(19) United States
(12) Patent Application Publication
(10) Pub. No.: US 2023/0215997 A1
(43) Pub. Date: Jul. 6, 2023

(54) DISPLAY DEVICE

(71) Applicant: Samsung Display Co., LTD., Yongin-si (KR)

(72) Inventor: Do Yeong PARK, Yongin-si (KR)

(21) Appl. No.: 17/966,659

(22) Filed: Oct. 14, 2022

(30) Foreign Application Priority Data
Jan. 3, 2022 (KR) 10-2022-0000421

(51) Int. Cl. H01L 33/60; H01L 33/20; H01L 33/38; H01L 33/62; H01L 27/15; H01L 33/50

(52) U.S. Cl. CPC H01L 33/60; H01L 33/20; H01L 33/382; H01L 33/62; H01L 27/156; H01L 33/505

(57) ABSTRACT

A display device includes: a pixel located on a substrate in a display area; and an optical structure located on the substrate in a non-display area, the optical structure including a first layer. A refractive index of the first layer is greater than a refractive index of the substrate.

### CROSS-REFERENCE TO RELATED APPLICATION

The application claims priority to, and the benefit of, Korean patent application 10-2022-0000421 filed on Jan. 3, 2022 in the Korean Intellectual Property Office, the entire disclosure of which is incorporated herein by reference.

### BACKGROUND

### 1. Field

The disclosure generally relates to a display device.

### 2. Description of Related Art

Recently, as interest in information displays is increased, research and development of display devices have been continuously conducted.

### SUMMARY

Embodiments provide a display device capable of reducing (or preventing) a light leakage phenomenon.

In accordance with an aspect of the disclosure, there is provided a display device including a substrate, a pixel on the substrate in a display area, and an optical structure on the substrate in a non-display area, and including a first layer, wherein a refractive index of the first layer is greater than a refractive index of the substrate.

The optical structure and the substrate may form an optical interface, wherein the display device further includes a middle layer on the substrate, the middle layer not overlapping with the optical interface in a plan view, and wherein a refractive index of the middle layer is less than the refractive index of the first layer.

The pixel may include a pixel circuit layer including a transistor, a first electrode and a second electrode on the pixel circuit layer, a first insulating layer over the first electrode and the second electrode, a light emitting element on the first insulating layer, a second insulating layer on the light emitting element, a first contact electrode and a second contact electrode electrically connected to the light emitting element, and a third insulating layer over the first contact electrode, and wherein the first layer includes a first optical layer in a same layer as the second insulating layer, and a second optical layer in a same layer as the third insulating layer.

One of the second insulating layer and the third insulating layer may include one of silicon nitride (SiNₓ), aluminum oxide (AlOₓ), and titanium oxide (TiOₓ).

The refractive index of the first layer may be greater by about 0.2 or more than the refractive index of the substrate.

The optical structure may further include a second layer between the middle layer and the first layer, wherein the second layer includes a reflective material.

The second layer may be on a base surface of the middle layer, wherein the base surface is inclined with respect to the substrate.

The second layer may include a reflective electrode layer in a same layer as the first electrode and the second electrode.

The display device may further include a third layer on the first layer, the third layer being configured to absorb light having a wavelength in a band, wherein the first layer and the third layer overlap with the optical interface in a plan view.

The pixel may include a first sub-pixel for emitting light of a first color, a second sub-pixel for emitting light of a second color, a third sub-pixel for emitting light of a third color, and a light emitting element included in each of the first sub-pixel, the second sub-pixel, and the third sub-pixel, the light emitting element being configured to emit light of the third color, wherein, in a plan view, the first sub-pixel overlaps with a first color filter that is configured to substantially block the light of the second color and the light of the third color, and that is configured to allow the light of the first color to be transmitted therethrough, wherein, in a plan view, the second sub-pixel overlaps with a second color filter that is configured to substantially block the light of the first color and the light of the third color, and that is configured to allow the light of the second color to be transmitted therethrough, wherein, in a plan view, the third sub-pixel overlaps with a third color filter that is configured to substantially block the light of the first color and the light of the second color, and is configured to allow the light of the third color to be transmitted therethrough, and wherein the third layer includes a same material as at least one of the first color filter and the second color filter.

The display device may further include an organic insulating layer on the first layer, wherein the third layer is on the organic insulating layer.

The middle layer may include one of silicon oxide (SiOₓ) and silicon oxynitride (SiOₓN_{y}).

The pixel may include a display element layer including a light emitting element, a low refractive layer above the display element layer, and a capping layer contacting the low refractive layer, wherein the display device further includes a low refractive valley between the display area and the optical structure, wherein a portion of the low refractive layer is accommodated in the low refractive valley, and wherein the optical structure is located outside of the low refractive valley in a plan view.

The capping layer might not overlap with the optical interface in a plan view.

The first layer and the substrate may be in contact with each other at the optical interface.

The pixel may include a light emitting element for emitting light, and a pixel circuit layer including a transistor electrically connected to the light emitting element, and an electrode layer, wherein light emitted from the light emitting element is reflected between the substrate, and an air layer outside of the substrate, and is reflected by the electrode layer, wherein at least a portion of the light emitted from the light emitting element is provided to the optical structure, and wherein the light provided to the optical structure is provided at an incident angle to the optical interface, and is transmitted at a transmission angle that is smaller than the incident angle through the optical structure.

The optical structure may include a plurality of island shapes.

The optical structure may include a bar shape extending in one direction.

The display device may further include a line area in the non-display area, and in which a line electrically connected to the pixel is located, wherein the line area is between the optical structure and the display area.

In accordance with another aspect of the disclosure, there is provided a display device including a substrate, a pixel including a pixel circuit layer that is on the substrate in the display area, and that includes an electrode layer, a display element layer that is on the pixel circuit layer, and that includes a light emitting element and an insulating layer, and a color filter layer that is on the display element layer, and that includes a color filter for absorbing light in a corresponding band, an optical refractive layer over the substrate in the non-display area, and including a same material as the insulating layer, and an optical absorption layer on the optical refractive layer, and including a same material as the color filter, wherein a refractive index of the optical refractive layer is greater than a refractive index of the substrate.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIGS. 1 and 2 are perspective and sectional views schematically illustrating a light emitting element in accordance with one or more embodiments of the disclosure.

FIG. 3 is a plan view schematically illustrating a display device in accordance with one or more embodiments of the disclosure.

FIG. 4 is a plan view schematically illustrating a sub-pixel in accordance with one or more embodiments of the disclosure.

FIGS. 5 and 6 are schematic sectional views taken along the line I-I′ shown in FIG. 4.

FIG. 7 is a schematic enlarged view of area EA1 shown in FIG. 3.

FIG. 8 is a sectional view schematically illustrating an optical structure in accordance with one or more embodiments of the disclosure.

FIG. 9 is a sectional view schematically illustrating the optical structure in accordance with one or more embodiments of the disclosure.

FIGS. 10 and 11 are views illustrating an aspect in which the optical structure prevents a light leakage phenomenon in accordance with one or more embodiments of the disclosure.

FIG. 12 is a schematic plan view distinctively expressing structures included in the optical structure in accordance with one or more embodiments of the disclosure.

FIG. 13 is a sectional view schematically illustrating an optical structure in accordance with one or more other embodiments of the disclosure.

FIG. 14 is a sectional view schematically illustrating an optical structure in accordance with one or more other embodiments of the disclosure.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The disclosure generally relates to a display device. Hereinafter, a display device in accordance with one or more embodiments of the disclosure will be described with reference to the accompanying drawings.

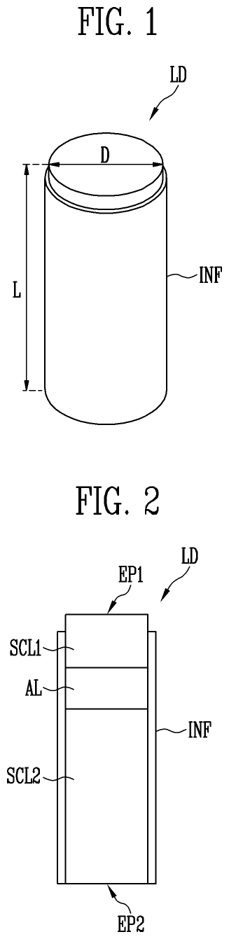

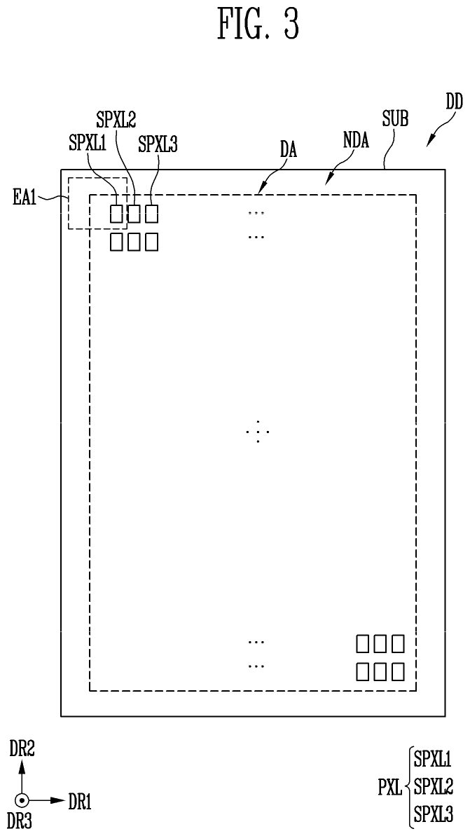

A light emitting element LD included in a display device (e.g., see display device DD shown in FIG. 3) in accordance with one or more embodiments of the disclosure is illustrated in FIGS. 1 and 2. FIGS. 1 and 2 are perspective and sectional views schematically illustrating a light emitting element in accordance with one or more embodiments of the disclosure. Although a pillar-shaped light emitting element LD is illustrated in FIGS. 1 and 2, the kind and/or shape of the light emitting element LD is not limited thereto.

Referring to FIGS. 1 and 2, the light emitting element LD includes a second semiconductor layer SCL2, a first semiconductor layer SCL1, and an active layer AL interposed between the first and second semiconductor layers SCL1 and SCL2. For example, when assuming that an extending direction of the light emitting element LD is a length L direction, the light emitting element LD may include the first semiconductor layer SCL1, the active layer AL, and the second semiconductor layer SCL2, which are sequentially stacked along the length L direction.

The light emitting element LD may be provided in a pillar shape extending along one direction. The light emitting element LD may have a first end portion EP1 and a second end portion EP2. The first semiconductor layer SCL1 may be adjacent to the first end portion EP1, and the second semiconductor layer SCL2 may be adjacent to the second end portion EP2.

The light emitting element LD may be a light emitting element manufactured in a pillar shape through an etching process, or the like. In this specification, the term “pillar shape” may include a rod-like shape or bar-like shape, which is long in the length L direction (e.g., its aspect ratio is greater than 1), such as a cylinder or a polyprism, and the shape of its section is not particularly limited. For example, a length L of the light emitting element LD may be greater than a diameter D (or a width of a cross-section) of the light emitting element LD.

The light emitting element LD may have a size of nanometer scale to micrometer scale. For example, the light emitting element LD may have a diameter D (or width) in a range of nanometer scale to micrometer scale, and/or may have a length L in a range of nanometer scale to micrometer scale. However, the size of the light emitting element LD is not limited thereto.

The first semiconductor layer SCL1 may be a first conductivity type semiconductor layer. The first semiconductor layer SCL1 is located on the active layer AL, and may include a semiconductor layer having a type that is different from a type of the second semiconductor layer SCL2. For example, the first semiconductor layer SCL1 may include a P-type semiconductor layer. In an example, the first semiconductor layer SCL1 may include at least one semiconductor material among InAlGaN, GaN, AlGaN, InGaN, AlN, and InN, and may include a P-type semiconductor layer doped with a first conductivity type dopant such as Mg. However, the material constituting the first semiconductor layer SCL1 is not limited thereto. In addition, the first semiconductor layer SCL1 may be configured with various materials.

The active layer AL is located on the second semiconductor layer SCL2, and may be formed in a single-quantum well structure or a multi-quantum well structure. The position of the active layer AL may be variously changed according to the kind of the light emitting element LD.

A clad layer doped with a conductive dopant may be formed on the top and/or the bottom of the active layer AL. For example, the clad layer may be an AlGaN layer or an InAlGaN layer. In some embodiments, a material such as AlGaN or AlInGaN may be used to form the active layer AL. In addition, the active layer AL may be configured with various materials.

The second semiconductor layer SCL2 may be a second conductivity type semiconductor layer. The second semiconductor layer SCL2 is located on the active layer AL, and may include a semiconductor layer having a type that is different from the type of the first semiconductor layer SCL1. For example, the second semiconductor layer SCL2 may include an N-type semiconductor layer. For example, the second semiconductor layer SCL2 may include any one semiconductor material among InAlGaN, GaN, AlGaN, InGaN, AlN, and InN, and include an N-type semiconductor layer doped with a second conductivity type dopant such as Si, Ge, or Sn. However, the material constituting the second semiconductor layer SCL2 is not limited thereto. In addition, the second semiconductor layer SCL2 may be configured with various materials.

When a voltage that is a threshold voltage or more is applied to both ends of the light emitting element LD, the light emitting element LD emits light as electron-hole pairs are combined in the active layer AL. The light emission of the light emitting element LD is controlled by using such a principle, so that the light emitting element LD can be used as a light source for various light emitting devices, including a pixel of a display device.

The light emitting element LD may further include an insulative film INF provided on a surface thereof. The insulative film INF may be formed on the surface of the light emitting element LD to substantially surround an outer circumferential surface of at least the active layer AL. In addition, the insulative film INF may further surround one areas of the first and second semiconductor layers SCL1 and SCL2. The insulative film INF may be formed as a single layer or a multi-layer. However, the disclosure is not limited thereto, and the insulative film INF may be configured with a plurality of layers. For example, the insulative film INF may include a first insulating layer including a first material, and a second insulating layer including a second material that is different from the first material.

The insulative film INF may expose both the end portions of the light emitting element LD, which have different polarities. For example, the insulative film INF may expose one end of each of the first and second semiconductor layers SCL1 and SCL2, which are respectively located at the first and second end portions EP1 and EP2 of the light emitting element LD. In one or more other embodiments, the insulative film INF may expose side portions of the first and second semiconductor layers SCL1 and SCL2 adjacent to the first and second end portions EP1 and EP2 of the light emitting element LD, which have different polarities.

The insulative film INF may be configured as a single layer or a multi-layer, including one material among silicon oxide (SiOₓ), silicon nitride (SiNₓ), silicon oxynitride (SiOₓN_{y}), aluminum oxide (AlOₓ), and titanium oxide (TiOₓ), but the disclosure is not limited thereto. For example, in accordance with one or more other embodiments, the insulative film INF may be omitted.

In accordance with one or more embodiments, when the insulative film INF is provided to cover the surface of the light emitting element LD, for example, the outer circumferential surface of the active layer AL, the electrical stability of the light emitting element LD can be ensured. Also, when the insulative film INF is provided on the surface of the light emitting element LD, a surface defect of the light emitting element LD is reduced or minimized, thereby improving the lifetime and efficiency of the light emitting element LD. In addition, even when a plurality of light emitting elements LD are densely located, the likelihood of an unwanted short circuit occurring between the light emitting elements LD can be reduced or prevented.

In accordance with one or more embodiments, the light emitting element LD may further include an additional component in addition to the first semiconductor layer SCL1, the active layer AL, the second semiconductor layer SCL2, and/or the insulative film INF surrounding the same. For example, the light emitting element LD may additionally include at least one phosphor layer, at least one active layer, at least one semiconductor layer, and/or at least one electrode layer, located at one ends of the first semiconductor layer SCL1, the active layer AL, and/or the second semiconductor layer SCL2. For example, a contact electrode layer may be further located at each of the first and second end portions EP1 and EP2 of the light emitting element LD.

FIG. 3 is a plan view schematically illustrating a display device in accordance with one or more embodiments of the disclosure.

The display device DD is configured to emit light. Referring to FIG. 3, the display device DD may include a substrate SUB and pixels PXL arranged on the substrate SUB. In one or more embodiments, the display device DD may further include a driving circuit (e.g., a scan driver and a data driver) for driving the pixels PXL, lines, and pads.

The display device DD may include a display area DA and a non-display area NDA. The non-display area NDA may mean an area except the display area DA. The non-display area NDA may surround at least a portion of the display area DA. In some embodiments, the display area DA may be designated as an active area, and the non-display area NDA may be designated as a non-active area.

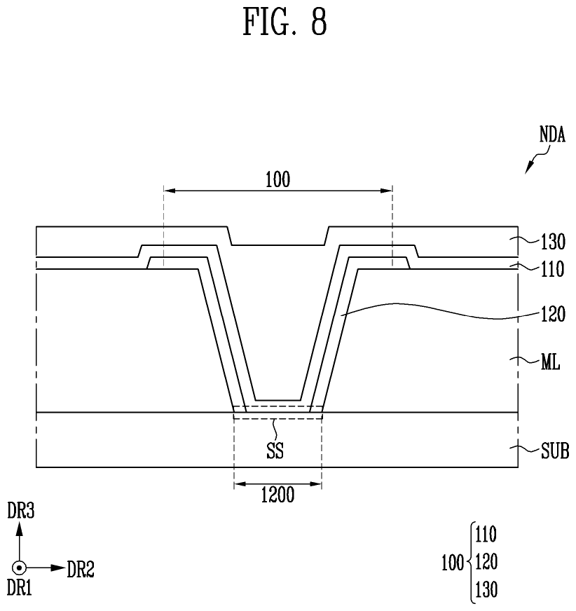

The substrate SUB may constitute a base member of the display device DD. The substrate SUB may be a rigid or flexible substrate or film, but the disclosure is not limited to a specific example. For example, the substrate SUB may be a rigid substrate made of glass or tempered glass, a flexible substrate (or thin film) made of a plastic or metal material, or at least one insulating layer. The material and/or property of the substrate SUB is not particularly limited. In accordance with one or more embodiments, a refractive index of the substrate SUB may be less than a refractive index of a first layer (e.g., see first layer 110 shown in FIG. 8). This will be described in detail later.

The display area DA may mean an area in which the pixels PXL are located. The non-display area NDA may mean an area in which the pixels PXL are not located. The driving circuit, the lines, and the pads, which are connected to the pixels PXL of the display area DA, may be located in the non-display area NDA.

For example, the pixels PXL may be arranged according to a stripe arrangement structure, a PENTILE™ arrangement structure (e.g., a RGBG matrix structure, a PENTILE™ matrix structure, a PENTILE™ structure, or an RGBG structure, PENTILE™ being a registered trademark of Samsung Display Co., Ltd., Republic of Korea), or the like. However, the disclosure is not limited thereto, and various embodiments known in the art may be applied.

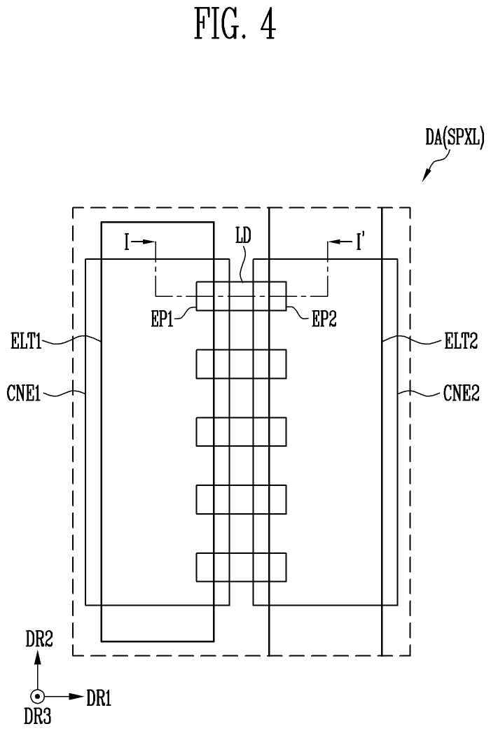

In accordance with one or more embodiments, the pixel PXL may include a first sub-pixel SPXL1, a second sub-pixel SPXL2, and a third sub-pixel SPXL3. Each of the first sub-pixel SPXL1, the second sub-pixel SPXL2, and the third sub-pixel SPXL3 may be a sub-pixel (e.g., see sub-pixel SPXL shown in FIG. 4). In some embodiments, the first sub-pixel SPXL1, the second sub-pixel SPXL2, and the third sub-pixel SPXL3 may constitute one pixel unit configured to emit lights of various colors.

For example, each of the first sub-pixel SPXL1, the second sub-pixel SPXL2, and the third sub-pixel SPXL3 may emit light of a color (e.g., predetermined color). In an example, the first sub-pixel SPXL1 may be a red pixel for emitting light of red (e.g., a first color), the second sub-pixel SPXL2 may be a green pixel for emitting light of green (e.g., a second color), and the third sub-pixel SPXL3 may be a blue pixel for emitting light of blue (e.g., a third color). However, the color, kind, and/or number of first, second, and third sub-pixels SPXL1, SPXL2, and SPXL3 constituting each pixel unit are not limited to a specific example.

FIG. 4 is a plan view schematically illustrating a sub-pixel in accordance with one or more embodiments of the disclosure. For example, a portion of the display area DA in which a sub-pixel SPXL is located is schematically illustrated in FIG. 4. The sub-pixel SPXL shown in FIG. 4 may be one of the first to third sub-pixels SPXL1, SPXL2, and SPXL3. FIG. 4 is one or more embodiments, and illustrates an arrangement structure of a plurality of light emitting elements LD connected in parallel between a first electrode ELT1 and a second electrode ELT2.

Referring to FIG. 4, the sub-pixel SPXL may include a first electrode ELT1, a second electrode ELT2, and light emitting elements LD located between the first electrode ELT1 and the second electrode ELT2. The sub-pixel SPXL may further include a first contact electrode CNE1 and a second contact electrode CNE2.

At least a portion of the light emitting element LD may be located between the first electrode ELT1 and the second electrode ELT2. The light emitting element LD may be aligned between the first electrode ELT1 and the second electrode ELT2.

The first electrode ELT1 and the second electrode ELT2 may be spaced apart from each other. For example, the first electrode ELT1 and the second electrode ELT2 may be spaced apart from each other along a first direction DR1 in each emission area (e.g., an emission area of each sub-pixel SPXL), and each of the first electrode ELT1 and the second electrode ELT2 may extend along a second direction DR2.

Each of the first electrode ELT1 and the second electrode ELT2 may have a pattern separated for each sub-pixel SPXL or may have a pattern commonly connected in a plurality of sub-pixels SPXL. For example, the first electrode ELT1 may have a pattern independent for each sub-pixel SPXL, and may be separated from first electrodes ELT1 of adjacent sub-pixels SPXL. The second electrode ELT2 may have a pattern independent for each sub-pixel SPXL, or may be integrally connected to second electrodes ELT2 of adjacent sub-pixels SPXL.

Meanwhile, in a process of forming sub-pixels SPXL, for example, before light emitting elements LD are completely aligned, first electrodes ELT1 of the sub-pixels SPXL may be connected to each other, and second electrodes ELT2 of the sub-pixels SPXL may be connected to each other. For example, before the light emitting elements LD are completely aligned, the first electrodes ELT1 of the sub-pixels SPXL may be integrally or non-integrally connected to constitute a first alignment line, and the second electrodes ELT2 of the sub-pixels SPXL may be integrally or non-integrally connected to constitute a second alignment line.

The first alignment line and the second alignment line may be respectively supplied with a first alignment signal and a second alignment signal in a process of aligning the light emitting elements LD. The first and second alignment signals may have different wavelengths, potentials, and/or phases. Accordingly, an electric field is formed between the first and second alignment lines, so that the light emitting elements LD can be aligned between the first and second alignment lines. After the light emitting elements LD are completely aligned, the first electrodes ELT1 of the sub-pixels SPX may be separated from each other by cutting at least the first alignment line. Accordingly, the sub-pixels SPX can be individually driven.

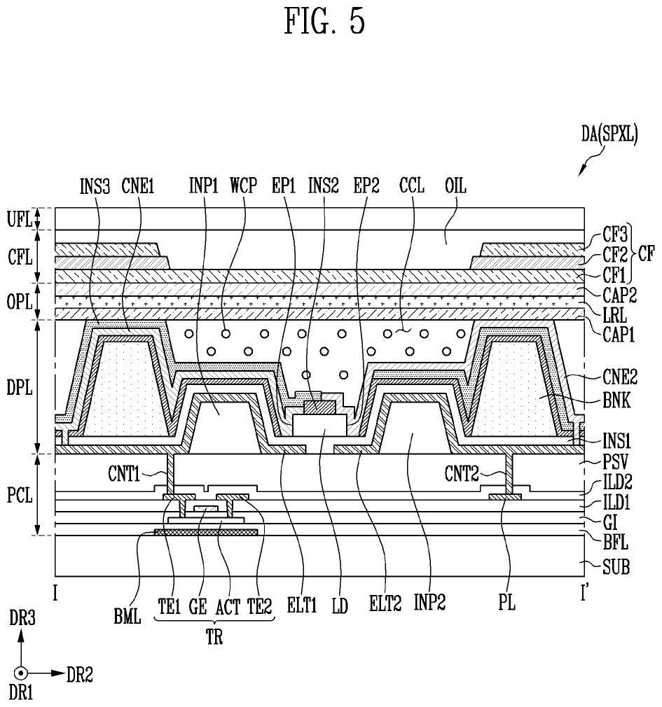

The first electrode ELT1 may be electrically connected to at least one circuit element, such as a transistor (e.g., see transistor TR shown in FIG. 5). The first electrode ELT1 may provide an anode signal.

The second electrode ELT2 may be electrically connected to a power line (e.g., see power line PL shown in FIG. 5). The second electrode ELT2 may provide a cathode signal.

Each of the first and second electrodes ELT1 and ELT2 may be configured as a single layer or a multi-layer. For example, each of the first and second electrodes ELT1 and ELT2 may include at least one reflective electrode layer including a reflective conductive material, and may selectively further include at least one transparent electrode layer and/or at least one conductive capping layer.

The light emitting elements LD may be aligned between the first electrode ELT1 and the second electrode ELT2. For example, the light emitting elements LD may be aligned and/or connected in parallel between the first electrode ELT1 and the second electrode ELT2.

In one or more embodiments, each light emitting element LD may be aligned in the first direction DR1 between the first electrode ELT1 and the second electrode ELT2 to be electrically connected to the first and second electrodes ELT1 and ELT2. Meanwhile, although a case where all the light emitting elements LD are uniformly aligned along the first direction DR1 is illustrated in FIG. 4, the disclosure is not limited thereto. For example, at least one of the light emitting elements LD may be arranged in an oblique direction inclined with respect to an extending direction of the first and second electrodes ELT1 and ELT2.

A first end portion EP1 of the light emitting element LD may be located adjacent to the first electrode ELT1, and a second end portion EP2 of the light emitting element LD may be located adjacent to the second electrode ELT2. The first end portion EP1 may or may not overlap with the first electrode ELT1. The second end portion EP2 may or may not overlap with the second electrode ELT2.

In one or more embodiments, the first end portion EP1 of each of the light emitting elements LD may be electrically connected to the first electrode ELT1 through the first contact electrode CNE1. In one or more other embodiments, the first end portion EP1 of each of the light emitting elements LD may be connected directly to the first electrode ELT1. In still one or more other embodiments, the first end portion EP1 of each of the light emitting elements LD is electrically connected to only the first contact electrode CNE1, and may not be connected to the first electrode ELT1.

Similarly, the second end portion EP2 of each of the light emitting elements LD may be electrically connected to the second electrode ELT2 through the second contact electrode CNE2. In one or more other embodiments, the second end portion EP2 of each of the light emitting elements LD may be connected directly to the second electrode ELT2. In still one or more other embodiments, the second end portion EP2 of each of the light emitting elements LD is electrically connected to only the second contact electrode CNE2, and may not be connected to the second electrode ELT2.

The light emitting elements LD may be provided (or prepared) in a form in which the light emitting elements LD are dispersed in a solution (e.g., predetermined solution), to be supplied to an emission area of each sub-pixel SPXL through an inkjet printing process, a slit coating process, or the like. When alignment signals (e.g., predetermined alignment signals) are applied to first and second electrodes ELT1 and ELT2 (or first and second alignment lines) of the sub-pixels SPXL in a state in which light emitting elements LD are supplied to each emission area, the light emitting elements LD are aligned between the first and second electrodes ELT1 and ELT2. After the light emitting elements LD are aligned, the solution may be removed through a drying process, or the like.

The first contact electrode CNE1 and the second contact electrode CNE2 may be respectively located over the first end portions EP1 and the second end portions EP2 of the light emitting elements LD.

The first contact electrode CNE1 may be located over the first end portions EP1 of the light emitting elements LD to be electrically connected to the first end portions EP1. In one or more embodiments, the first contact electrode CNE1 may be located on the first electrode ELT1 to be electrically connected to the first electrode ELT1. The first end portions EP1 of the light emitting elements LD may be connected to the first electrode ELT1 through the first contact electrode CNE1.

The second contact electrode CNE2 may be located over the second end portions EP2 of the light emitting elements LD to be electrically connected to the second end portions EP2. In one or more embodiments, the second contact electrode CNE2 may be located on the second electrode ELT2 to be electrically connected to the second electrode ELT2. The second end portions EP2 of the light emitting element LD may be connected to the second electrode ELT2 through the second contact electrode CNE2.

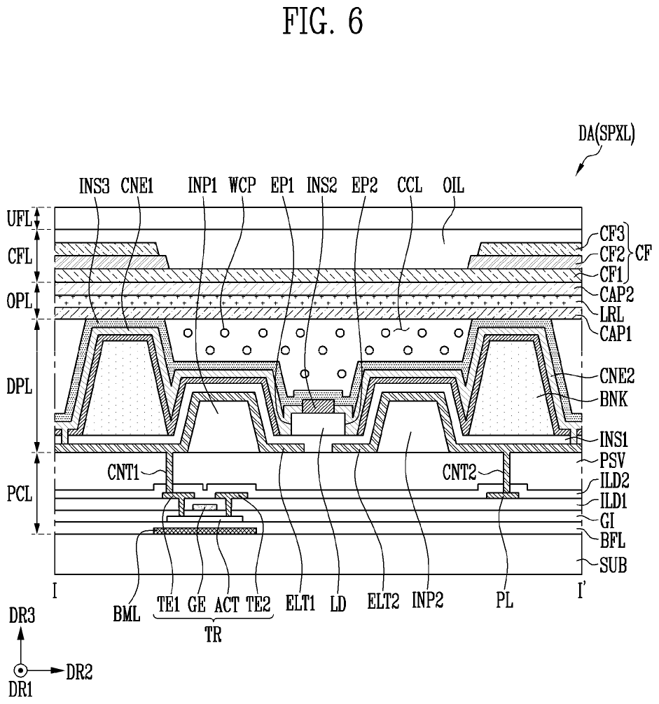

FIGS. 5 and 6 are schematic sectional views taken along the line I-I′ shown in FIG. 4. FIGS. 5 and 6 are sectional views schematically illustrating the sub-pixel SPXL in accordance with one or more embodiments of the disclosure. A stacked structure of the sub-pixel SPXL is mainly illustrated in FIGS. 5 and 6.

FIG. 5 may illustrate a sub-pixel SPXL in accordance with one or more embodiments of the disclosure, and FIG. 6 may illustrate a sub-pixel SPXL in accordance with one or more other embodiments of the disclosure. First, the sub-pixel SPXL in accordance with one or more embodiments of the disclosure will be described with reference to FIG. 5, and portions of the sub-pixel SPXL in accordance with the one or more other embodiments of the disclosure, which are different from those of the sub-pixel SPXL in accordance with the one or more other embodiments of the disclosure, will be mainly described with reference to FIG. 6.

Referring to FIG. 5, the sub-pixel SPXL may include a substrate SUB, a pixel circuit layer PCL, a display element layer DPL, an optical layer OPL, a color filter layer CFL, and upper film layer UFL.

The substrate SUB may form a base member of the sub-pixel SPXL. The substrate SUB may provide an area in which the pixel circuit layer PCL and the display element layer DPL can be located.

The pixel circuit layer PCL may be located on the substrate SUB. The pixel circuit layer PCL may include a lower auxiliary electrode BML, a buffer layer BFL, a transistor TR, a gate insulating layer GI, a first interlayer insulating layer ILD1, a second interlayer insulating layer ILD2, a power line, a protective layer PSV, a first contact part CNT1, and a second contact part CNT2.

The lower auxiliary electrode BML may be located on the substrate SUB. The lower auxiliary electrode BML may serve as a path through which an electrical signal is moved. In some embodiments, a portion of the lower auxiliary electrode BML may overlap with the transistor TR in a plan view.

The buffer layer BFL may be located on the substrate SUB. The buffer layer BFL may cover the lower auxiliary electrode BML. The buffer layer BFL may reduce or prevent an impurity otherwise diffused from the outside. The buffer layer BFL may include one of silicon oxide (SiOₓ), silicon nitride (SiNₓ), silicon oxynitride (SiOₓN_{y}), aluminum oxide (AlOₓ), and titanium oxide (TiOₓ).

The transistor TR may be a thin film transistor. In accordance with one or more embodiments, the transistor TR may be a driving transistor. The transistor TR may be electrically connected to a light emitting element LD.

The transistor TR may include an active layer ACT, a first transistor electrode TE1, a second transistor electrode TE2, and a gate electrode GE.

The active layer ACT may mean a semiconductor layer. The active layer ACT may be located on the buffer layer BFL. The active layer ACT may include one of poly-silicon, Low Temperature Polycrystalline Silicon (LTPS), amorphous silicon, and an oxide semiconductor.

The active layer ACT may include a first contact region in contact with the first transistor electrode TE1 and a second contact region in contact with the second transistor electrode TE2. The first contact region and the second contact region may correspond to a semiconductor pattern doped with an impurity. A region between the first contact region and the second contact region may be a channel region. The channel region may correspond to an intrinsic semiconductor pattern undoped with the impurity.

The gate electrode GE may be located on the gate insulating layer GI. A position of the gate electrode GE may correspond to that of the channel region of the active pattern ACT. For example, the gate electrode GE may be located on the channel region of the active pattern ACT with the gate insulating layer GI interposed therebetween.

The gate insulating layer GI may be located over the active pattern ACT. The gate insulating layer GI may include an inorganic material. In accordance with one or more embodiments, the gate insulating layer GI may include a material having a refractive index less than or equal to a refractive index of the substrate SUB. For example, when the refractive index of the substrate SUB is about 1.5, the refractive index of the gate insulating layer GI may be less than or equal to about 1.5.

The refractive index of the gate insulating layer GI may be less than the refractive index of the first layer 110 (see FIG. 8). In accordance with one or more embodiments, the gate insulating layer GI may include one of silicon oxide (SiOₓ) and silicon oxynitride (SiOₓN_{y}), but the disclosure is not necessarily limited to a specific example.

The first interlayer insulating layer ILD1 may be located over the gate electrode GE. The first interlayer insulating layer ILD1 may include an inorganic material. In accordance with one or more embodiments, the first interlayer insulating layer ILD1 may include a material having a refractive index less than or equal to the refractive index of the substrate SUB. For example, when the refractive index of the substrate SUB is about 1.5, the refractive index of the first interlayer insulating layer ILD1 may be less than or equal to about 1.5.

The refractive index of the first interlayer insulating layer ILD1 may be less than the refractive index of the first layer 110. In accordance with one or more embodiments, the first interlayer insulating layer ILD1 may include one of silicon oxide (SiOₓ) and silicon oxynitride (SiOₓN_{y}), but the disclosure is not necessarily limited to a specific example.

The first transistor electrode TE1 and the second transistor electrode TE2 may be located on the first interlayer insulating layer ILD1. The first transistor electrode TE1 may be in contact with the first contact region of the active pattern ACT while penetrating the gate insulating layer GI and the first interlayer insulating layer ILD1, and the second transistor electrode TE2 may be in contact with the second contact region of the active pattern ACT while penetrating the gate insulating layer GI and the first interlayer insulating layer ILD1. In an example, the first transistor electrode TE1 may be a drain electrode, and the second transistor electrode TE2 may be a source electrode. However, the disclosure is not limited thereto.

The first transistor electrode TE1 may be electrically connected to a first electrode ELT1 through the first contact part CNT1 formed on the protective layer PSV.

The second interlayer insulating layer ILD2 may be located over the first transistor electrode TE1, the second transistor electrode TE2, and the power line PL. The second interlayer insulating layer ILD2 may include an inorganic material. In accordance with one or more embodiments, the second interlayer insulating layer ILD2 may include a material having a refractive index that is less than or equal to the refractive index of the substrate SUB. For example, when the refractive index of the substrate SUB is about 1.5, the refractive index of the second interlayer insulating layer ILD2 may be less than or equal to about 1.5.

The refractive index of the second interlayer insulating layer ILD2 may be less than the refractive index of the first layer 110. In accordance with one or more embodiments, the second interlayer insulating layer ILD2 may include one of silicon oxide (SiOₓ) and silicon oxynitride (SiOₓN_{y}), but the disclosure is not necessarily limited to a specific example.

The power line PL may be located on the first interlayer insulating layer ILD1. The power line PL may be electrically connected to a second electrode ELT2 through the second contact part CNT2 formed in the protective layer PSV.

The protective layer PSV may be located on the second interlayer insulating layer ILD2. The protective layer PSV may include an inorganic material. In accordance with one or more embodiments, the protective layer PSV may include a material having a refractive index that is less than or equal to the refractive index of the substrate SUB. For example, when the refractive index of the substrate SUB is about 1.5, the refractive index of the protective layer PSV may be less than or equal to about 1.5.

The refractive index of the protective layer PSV may be less than the refractive index of the first layer 110. In accordance with one or more embodiments, the protective layer PSV may include one of silicon oxide (SiOₓ) and silicon oxynitride (SiOₓN_{y}), but the disclosure is not necessarily limited to a specific example. In some embodiments, the protective layer PSV may include an organic material. In some embodiments, the protective layer PSV may be a via layer.

The display element layer DPL may be located on the pixel circuit layer PCL. The display element layer DPL may include a first insulating pattern INP1, a second insulating pattern INP2, the first electrode ELT1, the second electrode ELT2, a first insulating layer INS1, a light emitting element LD, a second insulating layer INS2, a first contact electrode CNE1, a third insulating layer INS3, and a second contact electrode CNE2.

The first insulating pattern INP1 and the second insulating pattern INP2 may be located on the protective layer PSV. The first insulating pattern INP1 and the second insulating pattern INP2 may have a shape protruding in a thickness direction of the substrate SUB (e.g., a third direction DR3). The first insulating pattern INP1 and the second insulating pattern INP2 may include an organic material and/or an inorganic material.

The first electrode ELT1 and the second electrode ELT2 may be located on the protective layer PSV. In accordance with one or more embodiments, at least a portion of the first electrode ELT1 may be arranged over the first insulating pattern INP1, and at least a portion of the second electrode ELT2 may be arranged over the second insulating pattern INP2, to each serve as a reflective partition wall.

The first electrode ELT1 may be electrically connected to the transistor TR through the first contact part CNT1. The second electrode ELT2 may be electrically connected to the power line PL through the second contact part CNT2.

The first electrode ELT1 may be electrically connected to the light emitting element LD. The first electrode ELT1 may be electrically connected to the first contact electrode CNE1 through a contact hole formed in the first insulating layer INS1. The first electrode ELT1 may apply an anode signal to the light emitting element LD.

The second electrode ELT2 may be electrically connected to the light emitting element LD. The second electrode ELT2 may be electrically connected to the second contact electrode CNE2 through a contact hole formed in the first insulating layer INS1. The second electrode ELT2 may apply a cathode signal (e.g., a ground signal) to the light emitting element LD.

The first electrode ELT1 and the second electrode ELT2 may include a conductive material. For example, the first electrode ELT1 and the second electrode ELT2 may include one of silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the disclosure is not limited to the above-described example.

The first insulating layer INS1 may be located on the protective layer PSV. The first insulating layer INS may cover the first electrode ELT1 and the second electrode ELT2. The first insulating layer INS1 may stabilize connection between electrode components, and may reduce external influence. The first insulating layer INS1 may include one of silicon oxide (SiOₓ), silicon nitride (SiNₓ), silicon oxynitride (SiOₓN_{y}), aluminum oxide (AlOₓ), and titanium oxide (TiOₓ).

The light emitting element LD may be located on the first insulating layer INS1. The light emitting element LD may emit light, based on an electrical signal provided from the first contact electrode CNE1 and the second contact electrode CNE2. In accordance with one or more embodiments, the light emitting element LD may emit light of a third color (e.g., blue). A color conversion layer CCL and the color filter layer CFL are provided in sub-pixels SPXL, so that a full-color image can be displayed. However, the disclosure is not necessarily limited thereto, and light emitting elements LD emitting lights of different colors may be provided in each of the sub-pixels SPXL.

A portion of the second insulating layer INS2 may be located on the light emitting element LD. The second insulating layer INS2 may cover, or overlap, an active layer AL of the light emitting element LD.

The second insulating layer INS2 may include an inorganic material. In accordance with one or more embodiments, the second insulating layer INS2 may include a material having a refractive index that is greater than the refractive index of the substrate SUB. For example, the refractive index of the second insulating layer INS2 may be may be greater by about 0.2 or more than the refractive index of the substrate SUB. Alternatively, the refractive index of the second insulating layer INS2 may be may be greater by about 0.3 or more than the refractive index of the substrate SUB. In some embodiments, when the refractive index of the substrate SUB is about 1.5, the second insulating layer INS2 may have a refractive index of about 1.7 or more. For example, the second insulating layer INS2 may include one of silicon nitride (SiNₓ), aluminum oxide (AlOₓ), and titanium oxide (TiOₓ). However, the disclosure is not necessarily limited to the above-described example. In some embodiments, the second insulating layer INS2 may include an organic material having a refractive index that is greater than the refractive index of the substrate SUB.

In accordance with one or more embodiments, the refractive index of the second insulating layer INS2 may be greater than a refractive index of each layer of the pixel circuit layer PCL. The refractive index of the second insulating layer INS2 may be greater than a refractive index of a middle layer (e.g., see middle layer ML shown in FIG. 8). For example, the refractive index of the second insulating layer INS2 may be greater than the refractive index of each of the first and second interlayer insulating layers ILD1 and ILD2, the gate insulating layer GI, and the protective layer PSV.

In accordance with one or more embodiments, the second insulating layer INS2 may expose at least a portion of the light emitting element LD. For example, the second insulating layer INS2 might not cover or overlap a first end portion EP1 and a second end portion EP2 of the light emitting element LD. Accordingly, the first end portion EP1 and the second end portion EP2 of the light emitting element LD may be exposed, and may be electrically connected respectively to the first contact electrode CNE1 and the second contact electrode CNE2.

In accordance with one or more embodiments, a portion of the second insulating layer INS2 may be located on the first insulating layer INS1. For example, a portion of the second insulating layer INS2 may be located on, or above, the first insulating pattern INP1, the second insulating pattern INP2, and a bank BNK on the first insulating layer INS1. The second insulating layer INS2 may also expose at least a portion of the light emitting element LD.

The first contact electrode CNE1 and the second contact electrode CNE2 may be located on the first insulating layer INS1. In accordance with one or more embodiments, the first contact electrode CNE1 may be located on the first insulating layer INS1 and the second insulating layer INS2, and the second contact electrode CNE2 may be located on the first insulating layer INS1, the second insulating layer INS2, and the third insulating layer INS3.

The first contact electrode CNE1 and the second contact electrode CNE2 may be patterned through different processes. The first contact electrode CNE1 and the second contact electrode CNE2 may be provided at different times. For example, after the first contact electrode CNE1 is formed (or deposited), the second contact electrode CNE2 may be formed.

The first contact electrodes CNE1 may electrically connect the first electrode ELT1 and the light emitting element LD to each other, and the second contact electrode CNE2 may electrically connect the second electrode ELT2 and the light emitting element LD to each other.

The first contact electrode CNE1 and the second contact electrode CNE2 may include a conductive material. For example, the first contact electrode CNE1 and the second contact electrode CNE2 may include a transparent conductive material including Indium Tin Oxide (ITO), Indium Zinc Oxide (IZO), and Indium Tin Zinc Oxide (ITZO), but the disclosure is not limited thereto.

The third insulating layer INS3 may be located over the first contact electrode CNE1. The third insulating layer INS3 may reduce or prevent the likelihood of a short circuit between the first contact electrode CNE1 and the second contact electrode CNE2.

The third insulating layer INS3 may include an inorganic material. In accordance with one or more embodiments, the third insulating layer INS3 may include a material having a refractive index greater than the refractive layer of the substrate SUB. For example, the refractive index of the third insulating layer INS3 may be greater by about 0.2 or more than the refractive index of the substrate SUB. Alternatively, the refractive index of the third insulating layer INS3 may be greater by about 0.3 or more than the refractive index of the substrate SUB. In some embodiments, when the refractive index of the substrate SUB is about 1.5, the third insulating layer INS3 may have a refractive index of about 1.7 or more. For example, the third insulating layer INS3 may include one silicon nitride (SiNₓ), aluminum oxide (AlOₓ), and titanium oxide (TiOₓ). However, the disclosure is not necessarily limited to the above-described example. In some embodiments, the third insulating layer INS3 may include an organic material having a refractive index that is greater than the refractive index of the substrate SUB.

In accordance with one or more embodiments, the refractive index of the third insulating layer INS3 may be greater than a refractive index of each layer of the pixel circuit layer PCL. The refractive index of the third insulating layer INS3 may be greater than the refractive index of the middle layer ML. For example, the refractive index of the third insulating layer INS3 may be greater than the refractive index of each of the first and second interlayer insulating layers ILD1 and ILD2, the gate insulating layer GI, and the protective layer PSV.

In accordance with one or more embodiments, the display element layer DPL may further include a color conversion layer CCL. However, the disclosure is not necessarily limited to the above-described example. In some embodiments, the color conversion layer CCL may be separately provided in a layer that is different from the display element layer DPL.

The color conversion layer CCL may allow a wavelength of light provided from the light emitting element LD to be changed and/or transmitted therethrough.

For example, when the sub-pixel SPXL is a first sub-pixel SPXL1 emitting light of a first color (e.g., red), a wavelength conversion pattern WCP of the color conversion layer CCL may include first color conversion particles for converting light of the third color into light of the first color. The first color conversion particles may include a first quantum dot for converting light of blue into light of red. The first quantum dot may absorb blue light, and may emit red light by shifting a wavelength of the blue light according to energy transition.

In another example, when the sub-pixel SPXL is a second sub-pixel SPXL2 emitting light of a second color (e.g., green), the wavelength conversion pattern WCP of the color conversion layer CCL may include second color conversion particles for converting light of the third color into light of the second color. The second color conversion particles may include a second quantum dot for converting light of blue into light of green. The second quantum dot may absorb blue light, and may emit green light by shifting a wavelength of the blue light according to energy transition.

Meanwhile, the first quantum dot and the second quantum dot may have a shape, such as a spherical shape, a pyramid shape, a multi-arm shape, a cubic nano particle, a nano wire, a nano fabric, or a nano plate particle. However, the disclosure is not necessarily limited thereto, and the shape of the first quantum dot and the second quantum dot may be variously changed.

In still another example, in one or more embodiments, when the sub-pixel SPXL is a third sub-pixel SPXL3 emitting light of the third color (e.g., blue), the color conversion layer CCL may include a light transmission pattern. The light transmission pattern is used to efficiently use light emitted from the light emitting element LD, and may include a plurality of light scattering particles dispersed in a matrix material (e.g., predetermined matrix material), such as base resin. For example, the light transmission pattern may include light scattering particles, such as silica, but the material constituting the light scattering particles is not limited thereto.

The optical layer OPL may be located on the display element layer DPL. In accordance with one or more embodiments, the optical layer OPL may include a first capping layer CAP1, a low refractive layer LRL, and a second capping layer CAP2.

The first capping layer CAP1 may seal (or cover) the color conversion layer CCL. The first capping layer CAP1 may be located between the low refractive layer LRL and the display element layer DPL. The first capping layer CAP1 may be provided throughout the sub-pixels SPXL. The first capping layer CAP1 may reduce or prevent the likelihood of the color conversion layer CCL being damaged or contaminated due to infiltration of an impurity such as moisture or air from the outside.

In accordance with one or more embodiments, the first capping layer CAP1 may include at least one of silicon nitride (SiNₓ), silicon oxide (SiOₓ), silicon oxynitride (SiOₓN_{y}), and aluminum oxide (AlOₓ).

The low refractive layer LRL may be located between the first capping layer

CAP1 and the second capping layer CAP2. The low refractive layer LRL may be located between the color conversion layer CCL and the color filter layer CFL. The low refractive layer LRL may be provided throughout the sub-pixels SPXL.

The low refractive layer LRL may recycle light provided from the color conversion layer CCL, thereby improving light efficiency. To this end, the low refractive layer LRL may have a refractive index that is lower than a refractive index of the color conversion layer CCL.

In accordance with one or more embodiments, the low refractive layer LRL may include a base resin, and hollow particles dispersed in the base resin. The hollow particle may include a hollow silica particle. Alternatively, the hollow particle may be a pore formed by porogen, but the disclosure is not necessarily limited thereto. Also, the low refractive layer LRL may include one of a zinc oxide (ZnO) particle, a titanium dioxide (TiO₂) particle, and a nano silicate particle, but the disclosure is not necessarily limited thereto.

The second capping layer CAP2 may be located on the low refractive layer LRL. The second capping layer CAP2 may be located between the color filter layer CFL and the low refractive layer LRL. The second capping layer CAP2 may be provided throughout the sub-pixels SPXL. The second capping layer CAP2 may reduce or prevent the likelihood of the low refractive layer LRL being damaged or contaminated due to infiltration of an impurity, such as moisture or air from the outside.

In accordance with one or more embodiments, the second capping layer CAP2 may include one of silicon nitride (SiNₓ), silicon oxide (SiOₓ), silicon oxynitride (SiOₓN_{y}), and aluminum oxide (AlOₓ).

The color filter layer CFL may be located on the second capping layer CAP2. The color filter layer CFL may be provided throughout the sub-pixels SPXL. The color filter layer CFL may include color filters CF1, CF2, and CF3, and an organic insulating layer OIL.

The color filters CF1, CF2, and CF3 may be provided on the second capping layer CAP2.

In accordance with one or more embodiments, when the sub-pixel SPXL is the first sub-pixel SPXL1 emitting light of the first color, an emission area in which light of the light emitting element LD is emitted may overlap with a first color filter CF1, and might not overlap with a second color filter CF2 and a third color filter CF3, in a plan view. One or more embodiments in which the sub-pixel SPXL is the first sub-pixel SPXL1 is illustrated in FIG. 5.

In accordance with one or more embodiments, when the sub-pixel SPXL is the second sub-pixel SPXL2 emitting light of the second color, the emission area in which light of the light emitting element LD is emitted may overlap with the second color filter CF2, and might not overlap with the first color filter CF1 and the third color filter CF3, in a plan view.

In accordance with one or more embodiments, when the sub-pixel SPXL is the third sub-pixel SPXL3 emitting light of the third color, the emission area in which light of the light emitting element LD is emitted may overlap with the third color filter CF3, and might not overlap with the first color filter CF1 and the second color filter CF2, in a plan view.

The first color filter CF1 allows light of the first color to be transmitted therethrough, and may substantially block light of the second color and light of the third color not to be transmitted therethrough. In an example, the first color filter CF1 may include a colorant of the first color.

The second color filter CF2 allows light of the second color to be transmitted therethrough, and may substantially block light of the first color and light of the third color not to be transmitted therethrough. In an example, the second color filter CF2 may include a colorant of the second color.

The third color filter CF3 allows light of the third color to be transmitted therethrough, and may substantially block light of the first color and light of the second color not to be transmitted therethrough. In an example, the third color filter CF3 may include a colorant of the third color.

The organic insulating layer OIL may be located over the color filters CF1, CF2, and CF3. The organic insulating layer OIL may be provided throughout the sub-pixels SPXL. The organic insulating layer OIL may cover a lower member including the color filters CF1, CF2, and CF3. The organic insulating layer OIL may reduce or prevent moisture or air infiltrating into the above-described lower member. Also, the organic insulating layer OIL may protect the above-described lower member from a foreign matter, such as dust.

In accordance with one or more embodiments, the organic insulating layer OIL may include an organic material, such as acryl resin, epoxy resin, phenolic resin, polyamide resin, polyimide resin, unsaturated polyester resin, poly-phenylene ether resin, poly-phenylene sulfide resin, or benzocyclobutene (BCB). However, the disclosure is not necessarily limited to the above-described example.

The upper film layer UFL may be located on the color filter layer CFL. The upper film layer UFL may be located at an outer portion of the display device DD, to reduce external influence. The upper film layer UFL may be provided throughout the sub-pixels SPXL. In some embodiments, the upper film layer UFL may include one of a polyethylenephthalate (PET) film, a low reflective film, a polarizing film, and a transmittance controllable film, but the disclosure is not necessarily limited thereto.

Next, the sub-pixel SPXL in accordance with the one or more other embodiments of the disclosure will be described with reference to FIG. 6. In FIG. 6, descriptions of portions overlapping with those described above will be simplified or omitted.

The sub-pixel SPXL in accordance with the one or more other embodiments of the disclosure is different from the sub-pixel SPXL in accordance with one or more embodiments of the disclosure (FIG. 5), in that the first contact electrode CNE1 and the second contact electrode CNE2 are patterned through the same process.

Referring to FIG. 6, the first contact electrode CNE1 and the second contact electrode CNE2 may be formed through the same process. The first contact electrode CNE1 and the second contact electrode CNE2 may be located in a same layer.

For example, the first contact electrode CNE1 and the second contact electrode CNE2 may be provided at the same time to include the same material. As described above, the first contact electrode CNE1 and the second contact electrode CNE2 may include the same transparent conductive material.

In accordance with one or more embodiments, the first contact electrode CNE1 and the second contact electrode CNE2 may be spaced apart from each other, and may be covered by the third insulating layer INS3. For example, the third insulating layer INS3 may be located over the first contact electrode CNE1 and the second contact electrode CNE2 to protect individual components of the display element layer DPL including the first contact electrode CNE1 and the second contact electrode CNE2.

The disclosure is not necessarily limited to the above-described sub-pixel SPXL. For example, the sub-pixel SPXL may further include an additional insulating layer, and the structure of electrodes may be properly modified.

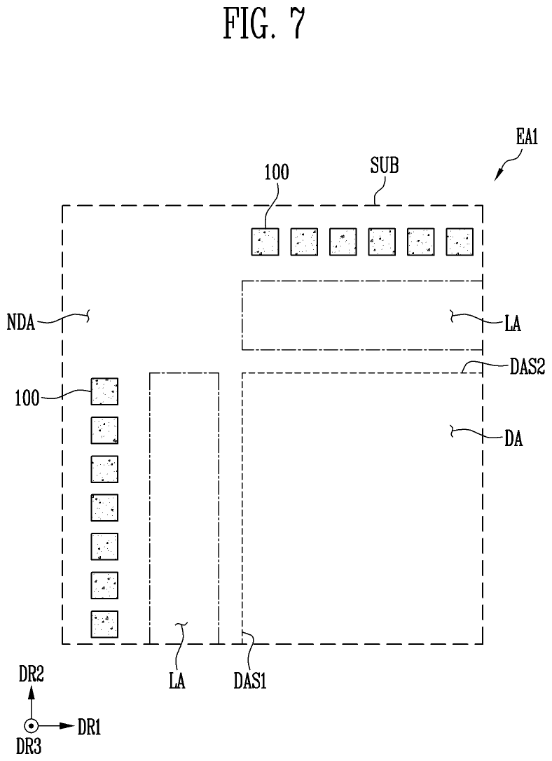

Hereinafter, an optical structure 100 in accordance with one or more embodiments of the disclosure will be mainly described with reference to FIGS. 7 to 14.

FIGS. 7 to 12 are views illustrating an optical structure 100 in accordance with one or more embodiments of the disclosure.

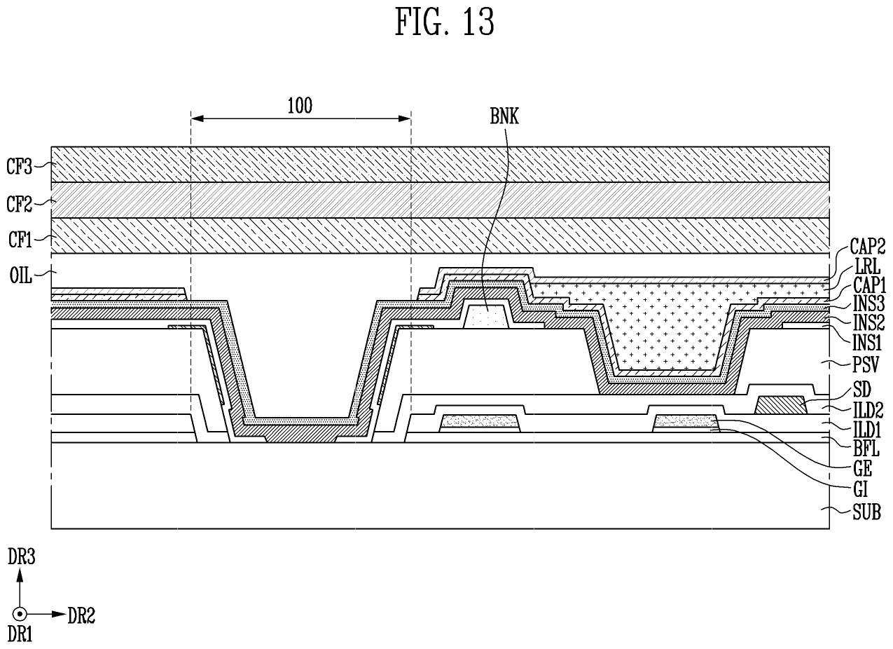

FIG. 13 is a view illustrating an optical structure 100 in accordance with a one or more other embodiments of the disclosure.

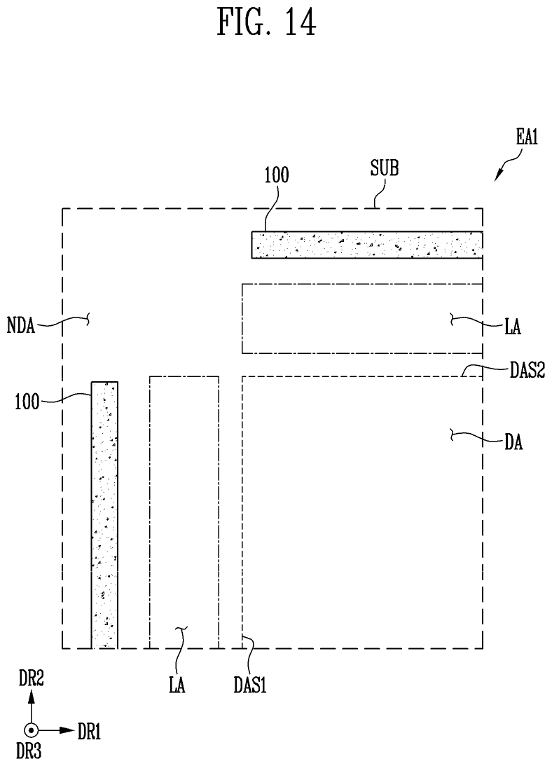

FIG. 14 is a view illustrating an optical structure 100 in accordance with one or more other embodiments of the disclosure.

First, the optical structure 100 in accordance with one or more embodiments of the disclosure will be described with reference to FIGS. 7 to 12.

FIG. 7 is a schematic enlarged view of area EA1 shown in FIG. 3. FIG. 7 illustrates a planar structure including the display area DA and the non-display area NDA.

Referring to FIG. 7, the non-display area NDA may have a shape surrounding at least a portion of the outside of the display area DA. For example, the non-display area NDA may surround a corner area of the display area DA. The non-display area NDA may include a line area LA.

In accordance with one or more embodiments, at least a portion of the line area LA may be located in the non-display area NDA. The line area LA may have a shape surrounding the display area DA. The line area LA may be an area in which a line through which an electrical signal for operating the display device DD is moved is located. For example, a power line provided in the pixel PXL, a line through which a scan signal is moved, a line through which a data signal is moved, and the like may be located in the line area LA.

The optical structure 100 may be located at the outside of the display area DA. The optical structure 100 may be located in the non-display area NDA. In a plan view, the optical structure 100 may be arranged in a shape surrounding the outside of the display area DA. The optical structure 100 is a structure for preventing and/or reducing a light leakage phenomenon, and may be located in the non-display area NDA along the outside of the display area DA, thereby reducing the light leakage phenomenon. A detailed structure in which the optical structure 100 reduces the light leakage phenomenon will be described later.

In some embodiments, an area in which the optical structure 100 is located may be designated as a light leakage reduction area.

The optical structure 100 may be provided in an island shape, to be provided in plurality. The optical structure 100 may be provided in plurality to be spaced apart from each other. For example, the optical structure 100 may be adjacent to a side DAS1 extending in the second direction DR2 of the display area DA to be arranged along the second direction DR2. The optical structure 100 may be adjacent to a side DAS2 extending in the first direction DR1 of the display area DA to be arranged along the first direction DR1. In accordance with one or more embodiments, a pattering process in which the optical structure 100 is located may be performed on the middle layer ML so as to form the optical structure 100. When a plurality of optical structures are formed in an island shape through the patterning process on the middle layer ML, the necessity to pattern a wide area in a lump is not necessarily required, and hence fairness can be improved.

In accordance with one or more embodiments, the optical structure 100 may have a quadrangular structure in a plan view. However, the disclosure is not necessarily limited thereto. For example, the optical structure 100 may be another polygonal shape. In some embodiments, the optical structure 100 may have a circular shape or an elliptical shape. In this specification, for convenience of description, one or more embodiments in which the optical structure 100 has a quadrangular shape in a plan view will be mainly described.

In accordance with one or more embodiments, the optical structure 100 may be located outside of the line area LA in a plan view. For example, the optical structure 100 may be more adjacent to an outermost portion of the substrate SUB than the display area DA and the line area LA. The optical structure 100 may be adjacent to one side of a line area LA1 extending in the second direction DR2, and the display area DA may be adjacent to the other side of the line area LA. The optical structure 100 may be adjacent to a line area LA extending in the first direction DR1, and the display area DA may be adjacent to the other side of the line area LA.

The optical structure 100 is located outside of, in plan view, the line area LA in which a line having a reflection property is located, so that the light leakage phenomenon can be more efficiently reduced or prevented.

FIG. 8 is a sectional view schematically illustrating an optical structure in accordance with one or more embodiments of the disclosure. In FIG. 8, an area (or structure) corresponding to the optical structure 100 is specified and illustrated on a sectional structure of the display device DD.

Referring to FIG. 8, the optical structure 100 may be located on the substrate SUB in the non-display area NDA. The optical structure 100 may include the first layer 110, a second layer 120, and a third layer 130.

The middle layer ML may be located on the substrate SUB. The middle layer ML may include any one of insulating layers included in the pixel circuit layer PCL. For example, the middle layer ML may be a layer including at least one of the first interlayer insulating layer ILD1, the second interlayer insulating layer ILD2, and the protective layer PSV. The refractive index of the middle layer ML may be less than the refractive index of the first layer 110. For example, the refractive index of the middle layer ML may be less by about 0.2 or more than the refractive index of the first layer 110.

The middle layer ML may form a base surface on which the first layer 110 and the second layer 120 are located. In accordance with one or more embodiments, the base surface may be provided with four sides. The base surface may be inclined with respect to the substrate SUB. The first layer 110 and the second layer 120 may be arranged on the base surface.

In accordance with one or more embodiments, when the middle layer ML is patterned, a groove (or valley) for forming the optical structure 100 may be provided. In accordance with one or more embodiments, when the middle layer ML is patterned, at least a portion of the substrate SUB may be exposed. When the middle layer ML is patterned, an optical contact area 1200 of the exposed substrate SUB may be an area in contact with at least a portion of the optical structure 100 as a subsequent process is performed. The optical contact area 1200 is an area included in the substrate SUB, and may be an area in which the middle layer ML is not located. For example, in a plan view, the middle layer ML might not overlap with an optical interface SS between the substrate SUB and the optical structure 100. The optical interface SS may mean a boundary surface between the substrate SUB and the optical structure 100.

In accordance with one or more embodiments, the first insulating layer INS1 may be further located between the first layer 110 and the second layer 120.

The first layer 110 may be located on the base surface of the middle layer ML. The first layer 110 may overlap with the substrate in a plan view. The first layer 110 may overlap with the optical contact area 1200 in a plan view. The first layer 110 may form the optical interface SS with the optical contact area 1200. For example, the first layer 110 may be substantially in contact with the optical contact area 1200.

In some embodiments, the first layer 110 may be designated as an optical refractive layer.

The first layer 110 may be located over the second layer 120. The first layer 110 may cover the second layer 120. A layer(s) included in the first layer 110 may be formed through a process subsequent to a process of forming a layer(s) included in the second layer 120. In accordance with one or more embodiments, the first layer 110 may be located in a same layer as at least one of the second insulating layer INS2 and the third insulating layer INS3. For example, the first layer 110 may be formed through the same process as at least one of the second insulating layer INS2 and the third insulating layer INS3 to include the same material. In some embodiments, a layer formed through the same process as the second insulating layer INS2 (or located in a same layer as the second insulating layer INS2) as a layer included in the first layer 110 may be designated as a first optical layer, and a layer formed through the same process as the third insulating layer INS3 (or located in a same layer as the third insulating layer INS3) as a layer included in the first layer 110 may be designated as a second optical layer.

The second layer 120 may be located on the base surface defined by the middle layer ML. The second layer 120 may be located between the middle layer ML and the first layer 110. The second layer 120 may include a reflective material, and may have a reflective property. In accordance with one or more embodiments, the second layer 120 may be located in a same layer as the first electrode ELT1 and the second electrode ELT2. For example, the second layer 120 may be formed through the same process as the first electrode ELT1 and the second electrode ELT2 to include the same material.

In some embodiments, the second layer 120 may be designated as an optical reflective layer.

The third layer 130 may be located on the first layer 110. At least a portion of the third layer 130 may overlap with the optical contact area 1200 in a plan view. For example, at least a portion of the third layer 130 may be inserted into the groove (or valley) defined by the middle layer ML. That is, in accordance with one or more embodiments, in a plan view, the substrate SUB, the first layer 110, and the third layer 130 may overlap with each other in the optical contact area 1200. In a plan view, the second layer 120 might not overlap with the substrate SUB.

In some embodiments, the third layer 130 may be designated as an optical absorption layer.

In accordance with one or more embodiments, the third layer 130 may absorb light having a wavelength in a band (e.g., predetermined band). The third layer 130 may be located in a same layer as at least one of the first color filter CF1 and the second color filter CF2. For example, the third layer 130 may be formed through the same process as at least one of the first color filter CF1 and the second color filter CF2 to include the same material.

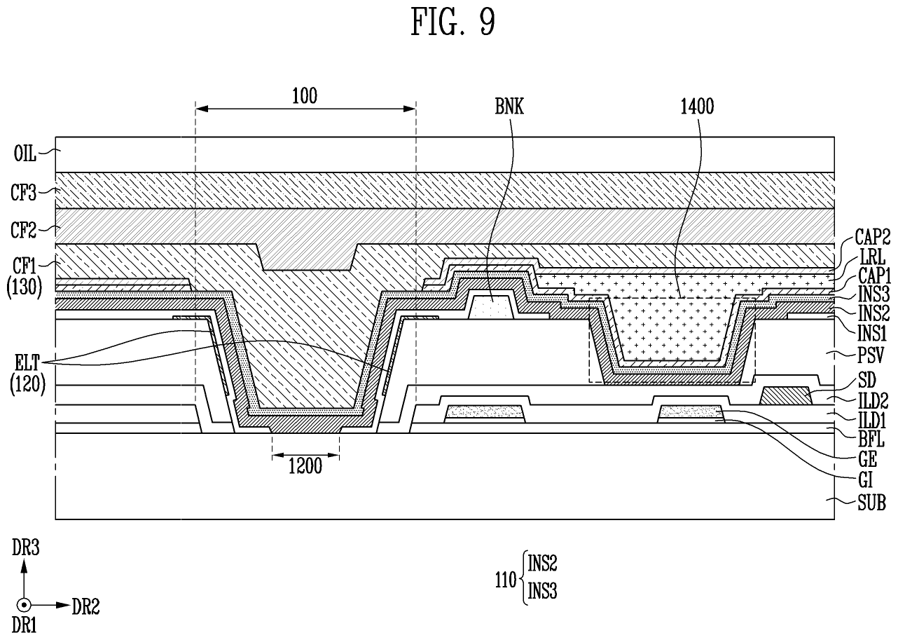

Hereinafter, the optical structure 100 will be described in more detail with reference to FIG. 9. FIG. 9 is a sectional view schematically illustrating the optical structure in accordance with one or more embodiments of the disclosure. The optical structure 100, and an area adjacent to an area in which the optical structure 100 is located, are illustrated in FIG. 9. In FIG. 9, a structure is illustrated, in which the substrate SUB, the gate insulating layer GI, the gate electrode GE, the buffer layer BFL, the first interlayer insulating layer ILD1, the second interlayer insulating layer ILD2, a source/drain electrode SD, and the protective layer PSV are located. The source/drain electrode SD may be formed through the same process as the first and second transistor electrodes TE1 and TE2 and the power line PL, which are described above, to include the same material as the first and second transistor electrodes TE1 and TE2 and the power line PL.

Referring to FIG. 9, the middle layer ML may include the first interlayer insulating layer ILD1, the second interlayer insulating layer ILD2, and the protective layer PSV. For example, the first interlayer insulating layer ILD1, the second interlayer insulating layer ILD2, and the protective layer PSV may not be located in the optical contact area 1200.

The first layer 110 of the optical structure 100 may include a portion of each of the second insulating layer INS2 and the third insulating layer INS3. For example, the second insulating layer INS2 and the third insulating layer INS3 may overlap with the optical contact area 1200 in a plan view.

The second layer 120 of the optical structure 100 may include a reflective electrode layer ELT. The reflective electrode layer ELT may be patterned through the same process as the first electrode ELT1 and the second electrode ELT2. The reflective electrode layer ELT may be located in a same layer as first electrode ELT1 and the second electrode ELT2 to include the same material. The reflective electrode layer ELT may be located at four sides of the protective layer PSV.

The first insulating layer INS1 may be located between the second layer 120 of the optical structure 100 and the reflective electrode layer ELT.

The third layer 130 of the optical structure 100 may include the first color filter CF1. For example, the first color filter CF1 may be provided in the groove (or valley) overlapping with the optical contact area 1200. However, the disclosure is not limited thereto, and one or more embodiments in which the third layer 130 includes the second color filter CF2 as described above may be provided.

The low refractive layer LRL in an area adjacent to the area in which the optical structure 100 is located may be located in a low refractive valley 1400 formed by the protective layer PSV. The optical structure 100 may be located more outwardly from the display device DD than the low refractive valley 1400. The low refractive valley 1400 may be located between the optical structure 100 and the display area DA. In accordance with one or more embodiments, the low refractive layer LRL provided in the low refractive valley 1400 may be provided through an inkjet process. When the inkjet process is performed, a fluid for providing the low refractive layer LRL is dispersed after the fluid is provided to the display area DA, and accordingly, the low refractive layer LRL may be entirely formed in the display device DD. After the groove (or valley) for forming the optical structure 100 is formed, the inkjet process on the low refractive layer LRL is performed. Hence, the fluid for providing the low refractive layer LRL is diffused, and therefore may be inappropriately located in the groove (or valley) for forming the optical structure 100. However, in accordance with one or more embodiments, because the low refractive valley 1400 is more adjacent to the display device DD than the optical structure 100, the fluid for providing the low refractive layer LRL is accommodated in the low refractive valley 1400. Thus, the likelihood of the fluid for providing the low refractive layer LRL being inappropriately diffused can be reduced or prevented. In addition, the bank BNK, which has a height at which the bank BNK is spaced further from the substrate SUB than the low refractive valley 1400, is formed between the optical structure 100 and the low refractive valley 1400 (e.g., in plan view), so that the likelihood of the fluid for providing the low refractive layer LRL being diffused can be further reduced or prevented.

In accordance with one or more embodiments, the first capping layer CAP1 may be formed before the low refractive layer LRL is formed, and the second capping layer CAP2 may be located on the low refractive layer LRL. In accordance with one or more embodiments, the first capping layer CAP1 and the second capping layer CAP2 might not overlap with the optical structure 100 in a plan view.

Meanwhile, although a structure in which the first color filter CF1 is provided in the groove (or valley) of the optical structure 100 has been illustrated in FIG. 9, the disclosure is not limited thereto. In some embodiments, a structure in which the second color filter CF2 is provided in the groove (or valley) of the optical structure 100 may be formed.

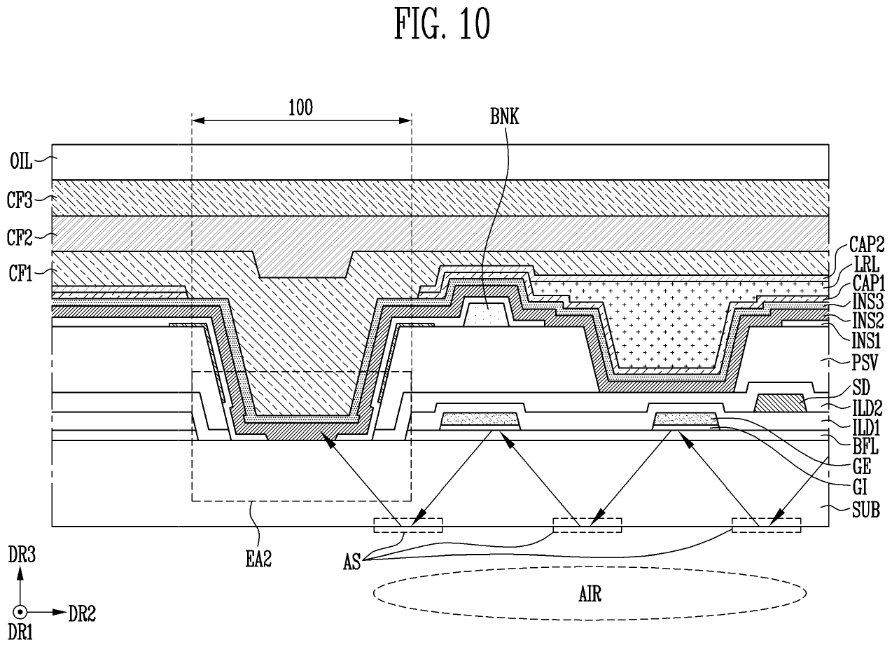

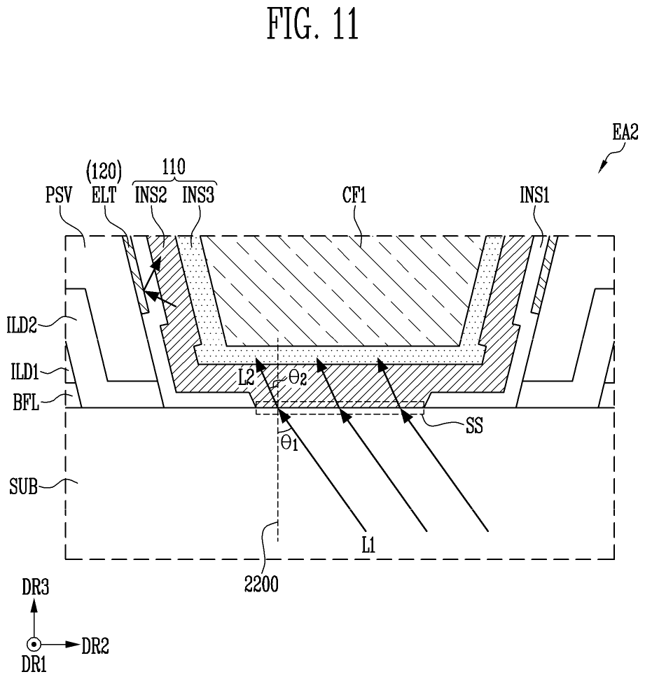

Hereinafter, light leakage reduction or prevention of the optical structure 100 will be described with reference to FIGS. 10 and 11. FIGS. 10 and 11 are views illustrating an aspect in which the optical structure reduces or prevents a light leakage phenomenon in accordance with one or more embodiments of the disclosure.

FIG. 10 is a view illustrating a path through which light emitted from the light emitting element LD is moved outward in the display device DD in accordance with one or more embodiments of the disclosure.

FIG. 11 is a schematic enlarged view of area EA2 shown in FIG. 10, and is a view schematically illustrating a state in which light leakage is reduced or prevented according to an interlayer refractive index difference of the optical structure 100.

Referring to FIG. 10, light emitted from the light emitting element LD may be diffused to the outside through the substrate SUB. For example, in conjunction with FIG. 5, light emitted from the light emitting element LD may be emitted to the substrate SUB through a gap, such as an area between the first electrode ELT1 and the second electrode ELT2. The light may be reflected through electrode layers (e.g., the gate electrode GE) located in the pixel circuit layer PCL, and may be totally reflected at an interface AS between the substrate SUB and an air layer AIR. Meanwhile, although a case where the emitted light is reflected by the gate electrode GE among the electrode layers of the pixel circuit layer PCL is mainly illustrated in FIG. 10, the disclosure is not limited thereto. For example, the emitted light may be reflected by other layers having a reflective property, such as the lower auxiliary electrode BML and the source/drain electrode SD.

Light provided from the light emitting element LD may be reflected by an electrode layer to face (e.g., travel) downwardly. The light facing downwardly may be totally reflected at the interface AS between the substrate SUB and the air layer AIR. Also, the light totally reflected at the interface AS between the substrate SUB and the air layer AIR may face (e.g., travel) upwardly, and may be again reflected by the electrode layer. Accordingly, the light provided from the light emitting element LD may be diffused to the outside of the display device DD between one surface (e.g., a surface adjacent to the air layer AIR) of the substrate SUB and the other surface (e.g., a surface adjacent to the pixel circuit layer PCL) of the substrate SUB.

In accordance with one or more embodiments, the refractive index of the substrate SUB may be greater than a refractive index of the air layer AIR. Accordingly, light provided at an angle (e.g., a predetermined angle) to the interface AS may be totally reflected and then diffused through the substrate SUB. For example, the refractive index of the substrate SUB may be greater than about 1.0. The refractive index of the substrate SUB may be about 1.4 to about 1.6. In an example, when the substrate SUB is provided as a glass substrate, the refractive index of the substrate SUB may be about 1.5. However, the disclosure is not necessarily limited to the above-described example.

There exists a possibility that light that is reflected between the electrode layer adjacent to the substrate SUB and the air layer AIR, and that is diffused to the outside, then will be viewed at the outside, and accordingly, a structure for blocking or reducing the likelihood of such possibility may be suitable.

The optical structure 100 in accordance with one or more embodiments of the disclosure may be provided as a structure for reducing or preventing the possibility in the display device DD.

Referring to FIG. 11, diffused light L1 that is diffused to the outside may be provided adjacent to the optical structure 100 at an angle (e.g., a predetermined angle). For example, the diffused light L1 may be provided at an incident angle 81 with respect to the optical interface SS between the optical structure 100 and the substrate SUB. The incident angle 81 is defined by a boundary line 2200 with respect to the optical interface SS and the incident angle of the diffused light.

Transmitted light L2 transmitted through the optical interface SS may be provided at an angle (e.g., a predetermined angle) to the optical structure 100. For example, the transmitted light L2 may be transmitted at a transmission angle 82 with respect to the optical interface SS between the optical structure 100 and the substrate SUB. The transmission angle 82 is defined by the boundary line 2200 with respect to the optical interface SS and the transmission angle of the transmitted light.

The diffused light L1 may be designated as first light, and the transmitted light L2 may be designated as second light.

In accordance with one or more embodiments, the refractive index of the first layer 110 of the optical structure 100 may be greater than the refractive index of the substrate SUB. For example, as described above, the refractive index of the first layer 110 may be greater by about 0.2 or more than the refractive index of the substrate SUB. Because one or more embodiments in which the second insulating layer INS2 and the third insulating layer INS3 are included in the first layer 110 is illustrated in FIG. 11, this will be mainly described. For example, a refractive index of the second insulating layer INS2 and the third insulating layer INS3 may be greater than the refractive index of the substrate SUB. Accordingly, the transmitted angle 82 may be smaller than the incident angle 81.

As described above, the optical structure 100 may form the optical interface SS with the substrate SUB. Accordingly, at least a portion of the diffused light L1 may be refracted with respect to the optical interface SS and then provided to the optical structure 100. Because the refractive index of the first layer 110 is provided to be greater than the refractive index of the substrate SUB, so that light is again reflected or diffused downwardly to the substrate SUB and can face the optical structure 100. That is, the path of the light is changed due to a refractive index difference between the substrate SUB and the first layer 110 (e.g., the second insulating layer INS2 and the third insulating layer INS3), so that an amount of light diffused to the outside can be reduced. Accordingly, a light leakage phenomenon can be reduced or prevented. In addition, the second insulating layer INS2 and the third insulating layer INS3 are components patterned through a process concurrently or substantially simultaneously performed with an individual layer of the display element layer DPL in the display area DA, and any separate process is not additionally required. Thus, process cost can be saved.

Meanwhile, in accordance with one or more embodiments, when the first layer 110 includes only the second insulating layer INS2, the refractive index of the second insulating layer INS2 may be greater than the refractive index of the substrate SUB, and the refractive index of the third insulating layer INS3 may be irrelevant to the refractive index of the substrate SUB. Similarly, when the first layer 110 includes only the third insulating layer INS3, the refractive index of the third insulating layer INS3 may be greater than the refractive index of the substrate SUB, and the refractive index of the second insulating layer INS2 may be irrelevant to the refractive index of the substrate SUB.

In accordance with one or more embodiments, light provided to the optical structure 100 may be reflected by the reflective electrode layer ELT, and then may be reflected to the inside of the optical structure 100. For example, the reflective electrode layer ELT is located at a boundary surface of the optical structure 100 and the middle layer ML, so that a portion of the light can be prevented from being again diffused to the outside through the middle layer ML. For example, the reflective electrode layer ELT is a component patterned through the same process as the first electrode ELT1 and the second electrode ELT2, and any separate process is not additionally required. Consequently, any process cost is not additionally required, and light leakage reduction or prevention efficiency can be further improved.

In accordance with one or more embodiments, the light provided into the optical structure 100 through the optical interface SS and the light reflected by the reflective electrode layer ELT may be absorbed by the third layer 130. Thus, the light provided to the optical structure 100 through the optical interface SS and the light reflected by the reflective electrode layer ELT can be prevented from being again diffused. For example, one or more embodiments in which the third layer 10 includes the first color filter CF1 is illustrated in FIG. 11. The first color filter CF1 may absorb light in a short wavelength band (e.g., blue light or the like as the third color). As described above, the light emitting element LD may emit light of the third color, and the light provided to the optical structure 100 may be light of the third color. The first color filter CF1 is configured to absorb light that may cause the light leakage phenomenon. Thus, the light leakage phenomenon can be further reduced. That is, the third layer 130 is located, which selectively absorbs a wavelength band corresponding to the wavelength of light emitted from the light emitting element LD in accordance with one or more embodiments of the disclosure. Thus, the light leakage phenomenon can be further reduced.

Meanwhile, as described above, one or more embodiments in which the third layer 130 includes the first color filter CF1 is not necessarily limited. For example, one or more embodiments may provide the third layer 130 that includes the second color filter CF2 when the light emitting element LD emits light of the third color. In addition, one or more embodiments may provide the third layer 130 that includes both the first color filter CF1 and the second color filter CF2.

Similarly, the configuration of the third layer 130 may be provided through a process performed in conjunction with a process in the display area DA. Accordingly, any additional process for manufacturing a separate light leakage reduction or prevention structure is not required.

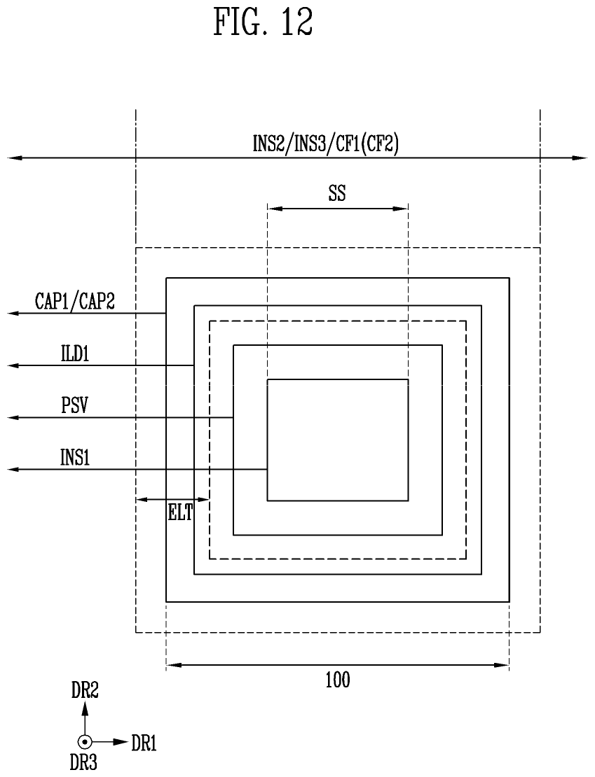

FIG. 12 is a schematic plan view distinctively expressing structures included in the optical structure in accordance with one or more embodiments of the disclosure. FIG. 12 may be a view clearly distinguishing a detailed structure of the optical structure 100 in accordance with one or more embodiments of the disclosure. FIG. 12 is one of embodiments, and a structure specified according to FIG. 9 will be mainly illustrated.

The second insulating layer INS2, the third insulating layer INS3, and the first color filter CF1 may overlap with each other at the optical interface SS between the substrate SUB and the optical structure 100, in a plan view. In some embodiments, the transmitted light LE may be mainly moved in an area in which the above-described components overlap with each other. In addition, the second insulating layer INS2, the third insulating layer INS3, and the second color filter CF2 may overlap with each other at the optical interface SS between the substrate SUB and the optical structure 100 in a plan view.

The first insulating layer INS1 may be located to expose the optical interface SS, to be provided to surround the outside with respect to the optical interface SS. That is, the first insulating layer INS1 may not overlap with the optical interface SS in a plan view.

The reflective electrode layer ELT might not overlap with the optical interface SS in a plan view. The reflective electrode layer ELT may be located adjacent to the optical interface SS. In some embodiments, the reflective electrode layer ELT may be selectively located at a position adjacent to the optical interface SS.

The protective layer PSV and the first interlayer insulating layer ILD1 might not overlap with the optical interface SS in a plan view. The protective layer PSV and the first interlayer insulating layer ILD1 may form four sides at which the optical structure 100 is located.

The first capping layer CAP1 and the second capping layer CAP2 may not overlap with the optical interface SS in a plan view. The first capping layer CAP1 and the second capping layer CAP2 may be formed earlier than the first color filter CF1 and the second color filter CF2. Accordingly, the first capping layer CAP1 and the second capping layer CAP2 are controlled not to at least overlap with the optical interface SS, so that the first color filter CF1 and the second color filter CF2 can be provided in the groove (or valley) in which the optical structure 100 is located.

Next, the optical structure 100 in accordance with one or more other embodiments of the disclosure will be described with reference to FIG. 13. In FIG. 13, descriptions of portions overlapping with those described above will be simplified or omitted. FIG. 13 is a sectional view schematically illustrating the optical structure.

Referring to FIG. 13, the optical structure 100 is different from the optical structure 100 described above, in that the organic insulating layer OIL is closer to the substrate SUB than the color filters CF1, CF2, and CF3.

The organic insulating layer OIL may be provided in the groove (or valley) in which the optical structure 100 is located. The organic insulating layer OIL may be located on the second insulating layer INS2 and the third insulating layer INS3.

Similarly, light diffused through the substrate SUB may be provided to the optical structure 100. The provided light may be provided to the first color filter CF1 via the organic insulating layer OIL. Accordingly, like the one or more embodiments described above, the light leakage phenomenon can be reduced.

Next, the optical structure 100 in accordance with one or more other embodiments of the disclosure will be described with reference to FIG. 14. In FIG. 14, descriptions of portions overlapping with those described above will be simplified or omitted. FIG. 14 is a sectional view schematically illustrating the optical structure.

Referring to FIG. 14, the optical structure 100 is different from the optical structure 100 described above in that the optical structure 100 has a bar shape.

In accordance with one or more embodiments, the optical structure 100 may have a shape extending in one direction. For example, the optical structure 100 adjacent to the side DAS1 extending in the second direction DR2 of the display area DA may extend in the second direction DR2. The optical structure 100 adjacent to the side DAS2 extending in the first direction DR1 of the display area DA may extend in the first direction DR1.

The optical structure 100 is continuously located as the outside of the display device DD, so that the light leakage phenomenon can be more surely prevented or reduced.

In accordance with the disclosure, there can be provided a display device capable of reducing (or preventing) a light leakage phenomenon.

Embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with any particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims, with functional equivalents thereof to be included therein.

What is claimed is:

1. A display device comprising:
a substrate;
a pixel on the substrate in a display area; and
an optical structure on the substrate in a non-display area, and comprising a first layer,
wherein a refractive index of the first layer is greater than a refractive index of the substrate.

2. The display device of claim 1, wherein the optical structure and the substrate form an optical interface,
wherein the display device further comprises a middle layer on the substrate, the middle layer not overlapping with the optical interface in a plan view, and
wherein a refractive index of the middle layer is less than the refractive index of the first layer.

3. The display device of claim 2, wherein the pixel comprises:
a pixel circuit layer comprising a transistor;
a first electrode and a second electrode on the pixel circuit layer;
a first insulating layer over the first electrode and the second electrode;
a light emitting element on the first insulating layer;
a second insulating layer on the light emitting element;
a first contact electrode and a second contact electrode electrically connected to the light emitting element; and
a third insulating layer over the first contact electrode, and
wherein the first layer comprises a first optical layer in a same layer as the second insulating layer, and a second optical layer in a same layer as the third insulating layer.

4. The display device of claim 3, wherein one of the second insulating layer and the third insulating layer comprise one of silicon nitride (SiNₓ), aluminum oxide (AlOₓ), and titanium oxide (TiOₓ).

5. The display device of claim 1, wherein the refractive index of the first layer is greater by about 0.2 or more than the refractive index of the substrate.

6. The display device of claim 3, wherein the optical structure further comprises a second layer between the middle layer and the first layer,
wherein the second layer comprises a reflective material.

7. The display device of claim 6, wherein the second layer is on a base surface of the middle layer, and
wherein the base surface is inclined with respect to the substrate.

8. The display device of claim 6, wherein the second layer comprises a reflective electrode layer in a same layer as the first electrode and the second electrode.

9. The display device of claim 2, further comprising a third layer on the first layer, the third layer being configured to absorb light having a wavelength in a band,
wherein the first layer and the third layer overlap with the optical interface in a plan view.

10. The display device of claim 9, wherein the pixel comprises:
a first sub-pixel for emitting light of a first color;
a second sub-pixel for emitting light of a second color;
a third sub-pixel for emitting light of a third color; and
a light emitting element comprised in each of the first sub-pixel, the second sub-pixel, and the third sub-pixel, the light emitting element being configured to emit light of the third color,
wherein, in a plan view, the first sub-pixel overlaps with a first color filter that is configured to substantially block the light of the second color and the light of the third color, and that is configured to allow the light of the first color to be transmitted therethrough,
wherein, in a plan view, the second sub-pixel overlaps with a second color filter that is configured to substantially block the light of the first color and the light of the third color, and that is configured to allow the light of the second color to be transmitted therethrough,
wherein, in a plan view, the third sub-pixel overlaps with a third color filter that is configured to substantially block the light of the first color and the light of the second color, and is configured to allow the light of the third color to be transmitted therethrough, and
wherein the third layer comprises a same material as at least one of the first color filter and the second color filter.

11. The display device of claim 10, further comprising an organic insulating layer on the first layer,
wherein the third layer is on the organic insulating layer.

12. The display device of claim 2, wherein the middle layer comprises one of silicon oxide (SiOₓ) and silicon oxynitride (SiOₓN_{y}).

13. The display device of claim 10, wherein the pixel comprises:
a display element layer comprising a light emitting element;
a low refractive layer above the display element layer; and
a capping layer contacting the low refractive layer,
wherein the display device further comprises a low refractive valley between the display area and the optical structure,
wherein a portion of the low refractive layer is accommodated in the low refractive valley, and
wherein the optical structure is located outside of the low refractive valley in a plan view.

14. The display device of claim 13, wherein the capping layer does not overlap with the optical interface in a plan view.

15. The display device of claim 2, wherein the first layer and the substrate are in contact with each other at the optical interface.

16. The display device of claim 2, wherein the pixel comprises:
a light emitting element for emitting light; and
a pixel circuit layer comprising a transistor electrically connected to the light emitting element, and an electrode layer,
wherein light emitted from the light emitting element is reflected between the substrate, and an air layer outside of the substrate, and is reflected by the electrode layer,
wherein at least a portion of the light emitted from the light emitting element is provided to the optical structure, and
wherein the light provided to the optical structure is provided at an incident angle to the optical interface, and is transmitted at a transmission angle that is smaller than the incident angle through the optical structure.

17. The display device of claim 1, wherein the optical structure comprises a plurality of island shapes.

18. The display device of claim 1, wherein the optical structure comprises a bar shape extending in one direction.

19. The display device of claim 17, further comprising a line area in the non-display area, and in which a line electrically connected to the pixel is located, wherein the line area is between the optical structure and the display area.

20. A display device comprising a display area and a non-display area, the display device comprising:
a substrate;
a pixel comprising:
a pixel circuit layer that is on the substrate in the display area, and that comprises an electrode layer;
a display element layer that is on the pixel circuit layer, and that comprises a light emitting element and an insulating layer; and
a color filter layer that is on the display element layer, and that comprises a color filter for absorbing light in a corresponding band;
an optical refractive layer over the substrate in the non-display area, and comprising a same material as the insulating layer; and
an optical absorption layer on the optical refractive layer, and comprising a same material as the color filter,
wherein a refractive index of the optical refractive layer is greater than a refractive index of the substrate.
